(19) United States
(12) Patent Application Publication
(10) Pub. No.: US 2026/0367201 A1
(43) Pub. Date: Nov. 19, 2026

(54) EXCITATION SUBSYSTEM OF IN-SITU MULTI-DIRECTIONAL IMAGING NUCLEAR MAGNETIC RESONANCE LOGGING SYSTEM

(71) Applicant: Jilin University, Changchun (CN)

(72) Inventors: Tingting Lin, Changchun (CN); Zhengping Li, Jilin (CN); Guangzhi Liao, Beijing (CN); Xing Gao, Changchun (CN); Hanqing Zhao, Fushun (CN)

(21) Appl. No.: 19/715,211

(22) Filed: Jun. 22, 2026

(30) Foreign Application Priority Data
Jan. 16, 2026 (CN) 202610059087.2

(51) Int. Cl. G01R 33/36

(52) U.S. Cl. CPC G01R 33/3614; G01R 33/3607

(57) ABSTRACT

Disclosed is an excitation subsystem of an in-situ multi-directional imaging nuclear magnetic resonance logging system, including four channels of class-E single-transistor power amplifiers with wide load impedance variation adaptability, a four-way lossless power combiner with wide load impedance variation adaptability, and a controller. The four-way lossless power combiner includes four bridge arms, each bridge arm is connected to one class-E single-transistor power amplifier, and matched with the impedance modulation ratio of the class-E single-transistor power amplifiers to integrate the voltage from the four output channels for exciting the load. The controller generates out-of-phase gate-control signals. The out-of-phase gate-control signals are input to the class-E single-transistor power amplifiers, and the phase of the output power of the four channels of class-E single-transistor power amplifiers is adjusted according to the outphasing modulation strategy. It can adapt to different load impedance conditions and achieve strong power output based on combining.

### CROSS-REFERENCE TO RELATED APPLICATIONS

This application claims to the benefit of priority from Chinese Application No. 202610059087.2 with a filing date of Jan. 16, 2026. The content of the aforementioned applications, including any intervening amendments thereto, are incorporated herein by reference.

### TECHNICAL FIELD

This disclosure relates to the technical field of nuclear magnetic resonance logging, in particular to an excitation subsystem of an in-situ multi-directional imaging nuclear magnetic resonance logging system.

### BACKGROUND

Tunnels, as a means of transportation that can break through natural spatial barriers and achieve effective connectivity between target areas, are widely present worldwide and are one of the important infrastructure in the transportation systems of countries around the world. Tunnels usually exist as important nodes for large highways, urban expressways, and cross sea passages, which are the core of improving the overall connectivity and integrity of the road network. However, during tunnel construction, hazardous water bodies such as underground water inrush, fissure water, and confined water pose a significant threat to the safety of construction personnel and the effectiveness of engineering construction investment. In global engineering practice, there are frequent cases of significant life and property losses due to tunnel water and mud inrush. Small-diameter nuclear magnetic resonance logging equipment is one of the effective solutions for automating the in-situ qualitative, quantitative, and positional identification of disaster water. It has the advantages of lossless detection and high detection efficiency in electromagnetic systems, as well as centimeter-level high resolution that traditional electromagnetic geophysical equipment does not possess.

However, traditional small-diameter nuclear magnetic resonance logging systems can only achieve non-selective polarization of circumferential samples, thereby only being able to extract basic information of disaster water bodies at measurement points, such that traditional systems are unable to provide further guidance for subsequent drainage work based on the specific spatial distribution intelligence of disaster water, which leads to blindness in related operations. This blindness will lead to a significant increase in construction costs, waste of human resources, and delays in the project schedule. The active multi-directional small-diameter nuclear magnetic logging probe based on multi-directional polarization sensing technology effectively solves this problem. However, achieving a highly integrated excitation subsystem in advanced drilling of extremely limited small-diameter tunnels to meet the multi-directional and efficient excitation requirements of high signal-to-noise ratio systems remains challenging, and exploring and applying appropriate technical solutions is an important factor in ensuring its practical application effectiveness.

### SUMMARY

This disclosed embodiment provides an excitation subsystem of an in-situ multi-directional imaging nuclear magnetic resonance logging system, which solves the problem that the excitation subsystem cannot meet the excitation requirements when multiple directions are simultaneously excited.

According to the present embodiment, an excitation subsystem of an in-situ multi-directional imaging nuclear magnetic resonance logging system is provided, which includes:

Four channels of class-E single-transistor power amplifiers with wide load impedance variation adaptability, configured to modulate an output voltage of a power supply to adapt to changes in load impedance;

A four-way lossless power combiner with wide load impedance variation adaptability, including four bridge arms, wherein each bridge arm connected to one channel of the class-E single-transistor power amplifiers with wide load impedance variation adaptability, and matched with an impedance modulation ratio of the class-E single-transistor power amplifiers with wide load impedance variation adaptability to integrate an voltage from four output channels for exciting the load;

A controller, configured to generate out-of-phase gate-control signals according to an out-of-phase angle, wherein the out-of-phase gate-control signals are input to gates of the four channels of the class-E single-transistor power amplifiers with wide load impedance variation adaptability, and a phase of output power of the four channels of the class-E single-transistor power amplifiers with wide load impedance variation adaptability is adjusted according to an outphasing modulation strategy.

Further, each channel of the class-E single-transistor power amplifiers with wide load impedance variation adaptability includes a power amplifier transistor E, a power supply resonant cavity, an output-series resonant cavity, and an output-parallel resonant cavity.

The power supply resonant cavity includes an inductor L_{f} and a capacitor C_{add}, a first end of the inductor L_{f} is connected to a positive terminal of the power supply, a second end of the inductor L_{f} is connected to a gate of the power amplifier transistor E, a source of the power amplifier transistor E is grounded and connected to a negative terminal of the power supply, the capacitor C_{add} is connected in parallel between a drain and the source of the power amplifier transistor E, and parasitic capacitance of the power amplifier transistor E and the capacitor C_{add} form the capacitance of the power supply resonant cavity.

The output-series resonant cavity includes an inductor Lₛ and a capacitor Cₛ connected in series, a first end of the inductor Lₛ is connected to the second end of inductor L_{f}, and a second end of inductor Lₛ is connected to a first end of capacitor Cₛ.

The output-parallel resonant cavity includes an inductor Lₚ and a capacitor C_{F}, one end of the inductor Lₚ is connected to a second end of the capacitor Cₛ and one end of the capacitor C_{F} to serve as an output end of the output-parallel resonant cavity, and the other end of the inductor L_{P} is connected to the other end of the capacitor C_{F} and grounded.

Further, the output-series resonant cavity satisfies:

$${C}_{s} = \frac{1}{2 π {f}_{sw} {R}_{min} {Q}_{s}}$$

Lₛ=Cₛ·(Rₘᵢₙ·Qₛ)

Where, f_{sw} is a power amplifier switching frequency, Rₘᵢₙ is a minimum load impedance within a range of load impedance variation adaptability, Qₛ is a design quality factor of the output-series resonant cavity, Cₛ is a capacitance value of the capacitor Cₛ, and Lₛ is an inductance value of the inductor Lₛ.

Further, the output-parallel resonant cavity satisfies:

$$\& {C}_{p} = \frac{{Q}_{p}}{2 π {f}_{sw} {R}_{max}}$$

$${L}_{p} = {( \frac{{R}_{max}}{{Q}_{p}} )}^{2} \cdot {C}_{p}$$

Where, Qₚ is a quality factor of the output-parallel resonant cavity, Rₘₐₓ is a maximum load impedance within a range of load impedance variation adaptability, Cₚ represents a capacitance value of capacitor Cₚ, Lₚ represents an inductance value of inductor Lₚ, and f_{sw} is a power amplifier switching frequency.

Further, the power supply resonant cavity satisfies:

\sqrt{L_{f}/C_{f}}=k_{f}Rₘᵢₙ, k_{f}∈[0.2,1.5];

f_{f}=kf_{sw}, k∈[1.3,1.5];

$${L}_{f} = - {k}_{f} {R}_{min} \cdot 2 π {f}_{sw} \cdot ( {L}_{f} {C}_{f} - \frac{1}{{( 2 π {f}_{sw} )}^{2}} ) ;$$

$${L}_{f} {C}_{f} = \frac{1}{{( 2 π {f}_{sw} )}^{2}} ;$$

Where, k is a resonance factor of the power supply resonant cavity, k_{f} is a impedance design factor, L_{f} is ab inductance value of inductance L_{f}, C_{f} is a capacitance value of the power supply resonant cavity, f_{sw} is a the power amplifier switching frequency, Rₘᵢₙ is a minimum load impedance within a range of load impedance variation adaptability, and f_{f} is a design resonance point frequency of the power supply resonant cavity.

Further, the four-way lossless power combiner with wide load impedance variation adaptability includes a first bridge arm, a second bridge arm, a third bridge arm, and a fourth bridge arm, an input side of each bridge arm is connected to one channel of the class-E single-transistor power amplifiers with wide load impedance variation adaptability, the first bridge arm includes an equivalent capacitor C₁, the second bridge arm includes an equivalent inductor L₁, the first bridge arm is connected in parallel with the second bridge arm and then connected to one end of the equivalent capacitor C₂, the third bridge arm includes an equivalent capacitor C₃, the fourth bridge arm includes an equivalent inductor L₂, the third bridge arm is connected in parallel with the fourth bridge arm and then connected to one end of the equivalent inductor L₃, the other end of the equivalent inductance L₃ and the other end of the equivalent capacitance C₂ together serve as output terminals of the four-way lossless power combiner with wide load impedance variation adaptability.

Further, an equivalent impedance of the first bridge arm is equal to an equivalent impedance of the third bridge arm and identical in impedance property, an equivalent impedance of the second bridge arm is equal to an equivalent impedance of the fourth bridge arm and identical in impedance property, the equivalent impedance of the first bridge arm is opposite to the equivalent impedance of the second bridge arm, and an equivalent impedance of parallel output terminals of the first bridge arm and the second bridge arm are equal to an equivalent impedance of parallel output terminals of the third bridge arm and the fourth bridge arm but with opposite impedance properties.

Further, the equivalent impedance of each bridge arm satisfies:

$${X}_{1} = \frac{{X}_{2}}{{k}_{comb} + \sqrt{{k}_{comb}^{2} - 1}} , {X}_{2} = \frac{2 {R}_{L}}{{k}_{comb} + 1} ;$$

Where, k_{comb} is a maximum degree of non-resistive fluctuation to balance the equivalent load of each bridge arm within a load impedance modulation ratio during an outphasing modulation process, R_{L} is the load impedance, X₁ is an absolute value of the equivalent impedance of the bridge arm, and X₂ is an absolute value of the equivalent impedance of the equivalent inductance L₃ or the equivalent capacitance C₂.

Further, outphasing modulation angles are:

$$θ = {cos}^{- 1} ( \sqrt{\frac{4 {V}_{s}^{4} + {P}_{out}^{2} {X}_{1}^{2}}{8 {P}_{out} {R}_{L} {V}_{s}^{2}}} ) ;$$

$$φ = {tan}^{- 1} ( \frac{{P}_{out} {X}_{1}}{2 {V}_{s}^{2}} ) ;$$

Where, θ and φ are both the outphasing modulation angles, Pₒᵤₜ is a peak power output of a combined channel, and Vₛ is a peak voltage output of a single-channel power amplifier.

Further, phases of output power of the four channels of the class-E single-transistor power amplifiers with wide load impedance variation adaptability is adjusted according to the outphasing modulation process strategy, including:
A phase shift of the class-E single-transistor power amplifiers with wide load impedance variation adaptability connected to the first bridge arm is recorded as zero;
A phase shift of the class-E single-transistor power amplifiers with wide load impedance variation adaptability connected to the third bridge arm is adjusted as 2θ;
A phase shift of the class-E single-transistor power amplifiers with wide load impedance variation adaptability connected to the second bridge arm is adjusted as 2φ;
A phase shift of the class-E single-transistor power amplifiers with wide load impedance variation adaptability connected to the fourth bridge arm is adjusted as 2θ+2φ.

The disclosed embodiments have at least the following technical effects:

The present disclosure provides an excitation subsystem for in-situ small-diameter nuclear magnetic resonance logging equipment with multi-directional imaging capability based on the signal-to-noise ratio model of the equipment and the probe characteristics of the in-situ small-diameter nuclear magnetic resonance logging equipment with multi-directional imaging capability. In-situ small-diameter nuclear magnetic resonance logging equipment with multi-directional imaging capability that can better meet the requirements of high signal-to-noise ratio design can achieve the active multi-directional imaging selection function required by multi-directional and efficient excitation capability, which is mainly characterized by high integration and efficient excitation. In addition, it can adapt to different load impedance conditions under various excitation schemes such as single-direction excitation or multi-directional simultaneous excitation, and achieve high-power output based on combining. Besides, by combining outphasing modulation strategy to directionally alter the equivalent impedance of the load from the excitation direction, a breakthrough in power amplitude is achieved, which can achieve output power amplitude adjustment similar to linear power amplifiers. Further, it enhances the in-situ working capability and application effect of in-situ small-diameter nuclear magnetic resonance logging equipment with multi-directional imaging capability.

### BRIEF DESCRIPTION OF THE DRAWINGS

FIG. 1 is a block diagram of the overall structure of an excitation subsystem provided by an embodiment of the present disclosure;

FIG. 2 is a structural schematic diagram of the probe provided by the embodiment of the present disclosure;

FIG. 3 is a schematic circuit diagram of a class-E single-transistor power amplifier with wide load impedance variation adaptability provided by the embodiment of the present disclosure;

FIG. 4 is a schematic circuit diagram of a four-way lossless power combiner with wide load impedance variation adaptability provided by the embodiment of the present disclosure;

FIG. 5 is a schematic diagram of the outphasing modulation strategy in the excitation subsystem provided by an embodiment of the present disclosure.

### DETAILED DESCRIPTION OF EMBODIMENTS

In order to make the purpose, technical solution, and advantages of this disclosure clearer and more understandable, the following will provide further detailed illustration of this disclosure in conjunction with the embodiments. It should be understood that the specific embodiments described herein are only used to explain the present disclosure and are not intended to limit the present disclosure.

The theoretical model of signal-to-noise ratio for high signal-to-noise ratio small-diameter nuclear magnetic resonance logging tool puts forward specific requirements for the performance of multiple core subsystems such as system polarization, excitation, perception, and reception processing. The nuclear magnetic resonance signal-to-noise ratio model is SNR=KF, where SNR is the nuclear magnetic resonance signal-to-noise ratio, K is the environmental factor for nuclear magnetic resonance signal-to-noise ratio, and F is the system parameter factor.

The environmental term for nuclear magnetic resonance signal-to-noise ratio is

$$K = \frac{16 N {µ}_{0}^{2} {γ}^{2} {ℏ}^{2} {I}_{s} ( {I}_{s} + 1 )}{3 \sqrt{2} {( {K}_{B} T )}^{3 / 2}} ,$$

where N represents the number of spins per unit volume that are in the resonant state, γ represents the gyromagnetic ratio, h represents the reduced Planck constant, I_{S} represents the spin quantum number, K_{B} represents the Boltzmann constant, T represents the ambient temperature, and [symbol] represents the vacuum permeability.

The system parameter factor is:

$$F = \frac{{iHf}_{L}^{2}}{\sqrt{Δ fR}} {( ln [ \frac{\sqrt{{P}_{r} γ} + \sqrt{2 π {f}_{L}}}{\sqrt{{P}_{r} γ} - \sqrt{2 π {f}_{L}}} ] )}^{2} ,$$

where i represents the current intensity, Δf represents the system receiving bandwidth, f_{L} represents the system operating frequency, R represents the coil resistance, H represents the magnetic field height in the sensitive area, Pᵣ represents the residual magnetization of the magnet material, and γ represents the gyromagnetic ratio.

According to the system signal-to-noise ratio model, the power output capability and applied frequency of the excitation subsystem of the system are positively correlated with the detection signal-to-noise ratio. According to the skin effect, for a small-diameter nuclear magnetic resonance logging system with high signal-to-noise ratio characteristics, its high operating frequency and the inherent property of wireline logging that increases linearly with detection depth determine that the excitation subsystem needs to be closely integrated with the probe to achieve a highly integrated system architecture, to avoid radio frequency power loss caused by cables as much as possible. Therefore, the ideal topology should be an electronic sub for nuclear magnetic logging connected to a logging probe through a connector, working together with the logging probe when going down the well.

Based on the above analysis, as an important structure in an electronic sub, the power amplifier module used to achieve system excitation function should have miniaturization, and the excitation subsystem suitable for multi-directional coil structure on the probe of in-situ small-diameter nuclear magnetic resonance logging tool with multi-azimuth imaging ability, which at least has miniaturization, high efficiency, high frequency working ability, and high power output ability.

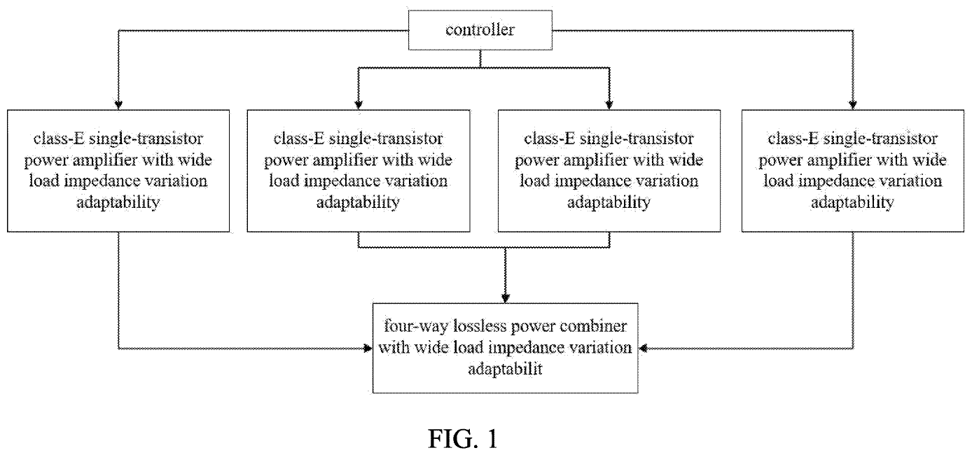

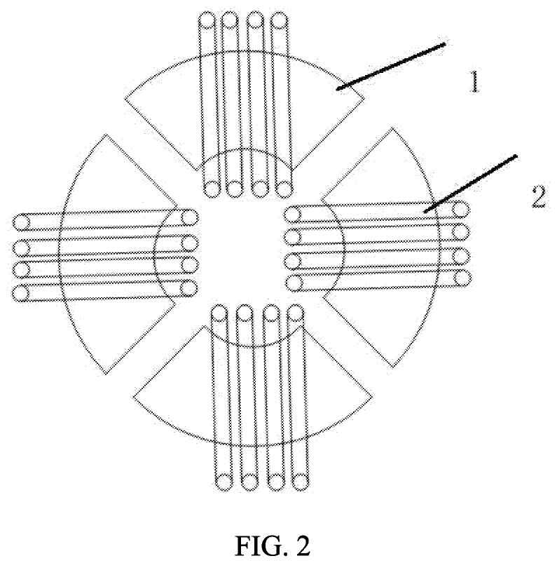

As shown in FIG. 1 and FIG. 2, an excitation subsystem of an in-situ multi-directional imaging nuclear magnetic resonance logging system in one embodiment of the present disclosure includes four channels of class-E single-transistor power amplifiers with wide load impedance variation adaptability. Each channel of the class-E single-transistor power amplifiers with wide load impedance variation adaptability passes through a bridge arm of a four-way lossless power combiner with wide load impedance variation adaptability. The output of the four-way lossless power combiner with wide load impedance variation adaptability is connected to four sets of transmitting coils (which serve as the loads) respectively through four sets of switches. In one example, as shown in FIG. 2, each set of transmitting coils 2 is wound around a fan-shaped polarization magnet 1, and there is a gap between the four fan-shaped polarization magnets 1 to form a circular ring. Each set of transmitting coils 2 faces one direction finding, and different direction findings can be selected for excitation through switches. Each transmitting coil 2 is individually excited, and different transmitting coils 2 are controlled through switches to achieve multi-directional detection. Each transmitting coil 2 serves as a load, With a determined load matching impedance, the equivalent impedance of the load can be multi-directionally changed within a certain range by the phase adjustment of the class-E single-transistor power amplifier with wide load impedance variation adaptability, thus achieving multi-directional adjustment of the power amplitude established by the power amplifier on the load.

The four channels of the class-E single-transistor power amplifiers with wide load impedance variation adaptability are used to modulate the output voltage of the power supply to make the output voltage adapt to the change in load impedance, to establish a stable radio frequency voltage on a determined load within the target design impedance modulation ratio range.

The four-way lossless power combiner with wide load impedance variation adaptability includes four bridge arms. Each bridge arm is connected to one class-E single-transistor power amplifier with wide load impedance variation adaptability, and matched with the impedance modulation ratio of the class-E single-transistor power amplifier with wide load impedance variation adaptability to excite the load after integrating the four output voltages, which can match with the impedance modulation ratio designed for the class-E single-transistor power amplifier with wide load impedance variation adaptability, achieving efficient power combination of four power amplifiers within the range.

A controller is further arranged to generate an out-of-phase gate-control signal according to the out-of-phase angle, and the out-of-phase gate-control signal is input to the gates of the four class-E single-transistor power amplifiers with wide load impedance variation adaptability, and the phase of the output power of the four class-E single-transistor power amplifiers with wide load impedance variation adaptability is adjusted according to the outphasing modulation strategy.

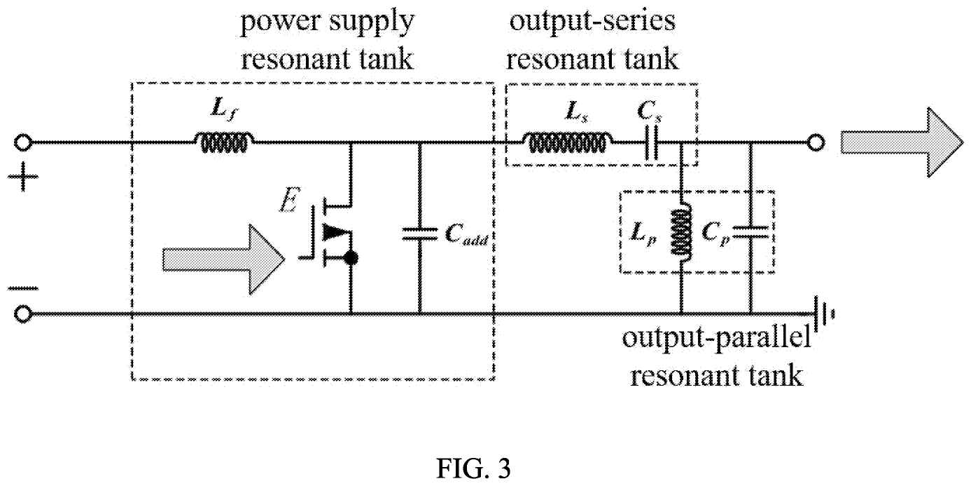

As shown in FIG. 3, the class-E single-transistor power amplifiers with wide load impedance variation adaptability includes a power amplifier transistor E and a three-stage resonant cavity consisting of a power supply resonant cavity, an output-series resonant cavity, and an output-parallel resonant cavity. Due to the extreme sensitivity of the class-E single-transistor power amplifiers to load impedance abrupt variation, conventional class-E single-transistor power amplifiers cannot achieve high efficiency and stable operation in this situation. Whether it is the passive output load abrupt variation caused by different direction finding excitation schemes or the active output load abrupt variation caused by the outphasing modulation strategy, both require adaptability to load impedance variations. Therefore, the design of the three-stage resonant cavity should aim to ensure that the power amplifier maintains zero-voltage switching in high-efficiency operation as much as possible within a wide range of load impedance variations. The output-series resonant cavity and the output-parallel resonant cavity provide comprehensive filtering services for the power amplifier output to ensure output linearity. While the power supply resonant cavity is configured to achieve high efficiency power supply for the entire power amplifier. The three resonant cavities can comprehensively achieve high efficiency, high linearity, and adaptability to load impedance variations within a certain range of the overall operation of the power amplifier.

Specifically, the output-series resonant cavity includes an inductor Lₛ and a capacitor Cₛ connected in series, which form a resonant relationship. The power supply resonant cavity includes an inductor L_{f} and a capacitor C_{add} connected in series. The first end of the inductor L_{f} is connected to the positive terminal of the power supply, and the second end of the inductor L_{f} is connected to the gate of the power amplifier transistor E. The source of the power amplifier transistor E is grounded and connected to the negative terminal of the power supply. The capacitor C_{add} is connected in parallel between the drain and the source of the power amplifier transistor E. The power amplifier transistor E has a parasitic capacitance Cₚₐᵣₐ, and the power amplifier transistor E is connected in parallel with the capacitor C_{add}. The capacitor C_{add} and the parasitic capacitor Cₚₐᵣₐ are connected in parallel to form capacitor C_{f} of the power supply resonant cavity. The capacitor C_{add} is a supplementary part of the capacitor C_{f} required to construct the power supply resonant cavity. The output-parallel resonant cavity includes an inductor Lₚ and a capacitor Cₚ, which form a resonant relationship.

The first end of inductor L_{f} is connected to the positive terminal of the power supply, the second end of inductor L_{f} is connected to the collector of the power amplifier transistor E, the emitter of the power amplifier transistor E is grounded and connected to the negative terminal of the power supply, the capacitor C_{add} is connected in parallel between the collector and the emitter of the power amplifier transistor E, and the first end of the output-series resonant cavity is connected to the second end of the inductor L_{f}.

The output-series resonant cavity includes an inductor Lₛ and a capacitor Cₛ connected in series. The first end of the inductor Lₛ is connected to the second end of inductor L_{f}, and the second end of inductor Lₛ is connected to the first end of the capacitor Cₛ.

The output-parallel resonant cavity includes an inductor Lₚ and a capacitor Cₚ. One end of the inductor Lₚ is connected to the second end of the capacitor Cₛ and connected to one end of the capacitor Cₚ, serving as the output end of the class-E single-transistor power amplifier. The other end of the inductor Lₚ is connected to the other end of the capacitor Cₚ and grounded.

The output-parallel resonant cavity and the output-series resonant cavity need to balance the Q value (quality factor) of the resonant cavity and stability issues. In high linearity applications, it is often required to maximize the filtering effect at the output end of the power amplifier. However, the Q value of the resonant cavity that can be stably achieved based on passive components is limited, so careful consideration is required. The Q value of the resonant cavity of these two stages of resonant cavities needs to be selected between 2-10 to balance filtering effect and stability issues.

According to the circuit structure, the passive components in the output-series resonant cavity meet the following requirements:

$${C}_{s} = \frac{1}{2 π {f}_{sw} {R}_{min} {Q}_{s}} ;$$

Lₛ=Cₛ·(Rₘᵢₙ·Qₛ);

Where, f_{sw} is the power amplifier switching frequency, Rₘᵢₙ is the minimum load impedance within the range of load impedance variation adaptability, Qₛ is the design quality factor of the output-series resonant cavity, Cₛ represents the capacitance value of the capacitor Cₛ, and Lₛ represents the inductance value of the inductor Lₛ.

The output-parallel resonant cavity meets the following requirements:

$$\& {C}_{p} = \frac{{Q}_{p}}{2 π {f}_{sw} {P}_{max}} ;$$

$${L}_{p} = {( \frac{{R}_{max}}{{Q}_{p}} )}^{2} \cdot {C}_{p} ;$$

Qₚ is the design quality factor of the output-parallel resonant cavity, Rₘₐₓ is the maximum load impedance within the range of the load impedance variation adaptability, Cₚ represents the capacitance value of the capacitor Cₚ, and Lₚ represents the inductance value of the inductor Lₚ.

In addition, the power supply resonant cavity needs to balance the impedance value at the switching frequency and the size of the load impedance modulation ratio that the power amplifier can achieve in its ideal operating state. Although a larger impedance at switching frequency can reduce power consumption, it can lead to a decrease in the achievable load impedance modulation ratio under ideal operating state. Load impedance modulation ratio refers to the ratio of the maximum and minimum variations in output power under different load impedance conditions. Therefore, the values of the impedance design factor k_{f} and the resonant factor k of the power supply resonant cavity need to be balanced, wherein the impedance design factor k_{f} should be reasonably designed within the range of 0.2-1.5, while the resonant factor k of the power supply resonant cavity should be designed within the range of 1.29-1.5. The combination of the two factors affects the power supply loss and the achievable load impedance modulation ratio under ideal operating state. Due to their mutual influence, the impedance design factor k_{f} is gradually increased to ensure the effectiveness of the positive load impedance modulation ratio under the premise of determining the appropriate resonant factor k value for the power supply resonant cavity.

As the load impedance variations, the ideal resonant frequency of the power supply resonant cavity for achieving zero voltage switching (ZVS) will also change accordingly. The amplitude of this frequency offset is inversely proportional to the network impedance of the power supply resonant cavity: at a given load impedance modulation ratio, a higher network impedance of the power supply resonant cavity will result in a larger zero voltage switching (ZVS) frequency offset. In practical applications, the setting of the network impedance of the power supply resonant cavity needs to strike a balance between power loss and adaptability to load impedance conditions to ensure that the power supply resonant cavity can achieve zero voltage switching.

In one embodiment, the parameters of the power supply resonant cavity satisfy the following formula, which is used to achieve zero voltage switching:

\sqrt{L_{f}/C_{f}}=k_{f}Rₘᵢₙ, k_{f}∈[0.2,1.5];

f_{f}=kf_{sw}, k∈[1.3,1.5];

$${L}_{f} = - {k}_{f} {R}_{min} \cdot 2 π {f}_{sw} \cdot ( {L}_{f} {C}_{f} - \frac{1}{{( 2 π {f}_{sw} )}^{2}} ) ;$$

$${L}_{f} {C}_{f} + \frac{1}{{( 2 π {f}_{f} )}^{2}} ;$$

Where, k is the resonance factor of the power supply resonant cavity, k_{f} is the impedance design factor, L_{f} is the inductance value of inductor L_{f}, C_{f} is the capacitor value of the power supply resonant cavity, f_{sw} is the power amplifier switching frequency, Rₘᵢₙ is the minimum load impedance within the range of load impedance variation adaptability, and f_{f} is the design resonance at frequency of the power supply resonant cavity.

In one example, for a multi-directional imaging in-situ small-diameter nuclear magnetic resonance logging system with high signal-to-noise ratio characteristics, how to further expand the output power of the radio frequency power amplifier at higher frequencies within an extremely limited design space is always an important and difficult problem. To ensure the excitation effect, the highly integrated design structure of the electronic sub that can be lowered into the well with the probe determines that linear amplifiers with larger dimensions are difficult to apply. GaN MOSFET (gallium nitride metal oxide semiconductor field effect transistor) has a lower total gate charge and high voltage capability at the same power level, resulting in a smaller package size. According to the formula:

$${T}_{sw} = \frac{{Q}_{g}}{{I}_{g}}$$

Where, T_{sw} is the driving state transition time of the GaN MOSFET, Q_{g} is the total gate charge, I_{g} is the gate driving current, and a lower total gate charge makes the state transition time of GaN MOSFET shorter under certain driving conditions. Therefore, it makes it very suitable for the design requirements of the excitation subsystem of miniaturized nuclear magnetic resonance logging tool in the context of high signal-to-noise ratio.

Therefore, in one embodiment, the power amplifier transistor E of the class-E single-transistor power amplifier with wide load impedance variation adaptability adopts GaN MOSFET. Compared with the D-class full bridge topology, the class-E single-transistor power amplifier based on resonant cavity has higher design flexibility and expansion space. However, as the core power amplifier component, the GaN MOSFET needs to directly face the threat of higher peak resonant voltage caused by the high Q value of the resonant cavity, so its power supply voltage is limited. This results in a single set of the class-E single-transistor power amplifier with wide load impedance variation adaptability having lower power output capability.

Although the power output capability of a single set of the class-E single-transistor power amplifier is limited, significant enhancement of output power on the load can be achieved through multi-channels of class-E single-transistor power amplifiers with wide load impedance variation adaptability, a four-way lossless power combiner with wide load impedance variation adaptability, and equivalent outphasing modulation of the load impedance. The four-way lossless power combiner with wide load impedance variation adaptability is a four-way structure, and the bridge arm impedance of each way needs to ensure the near-resistance variation within the load impedance modulation ratio as much as possible as the ultimate goal, in order to minimize the decrease in combining efficiency caused by circulating reactive power.

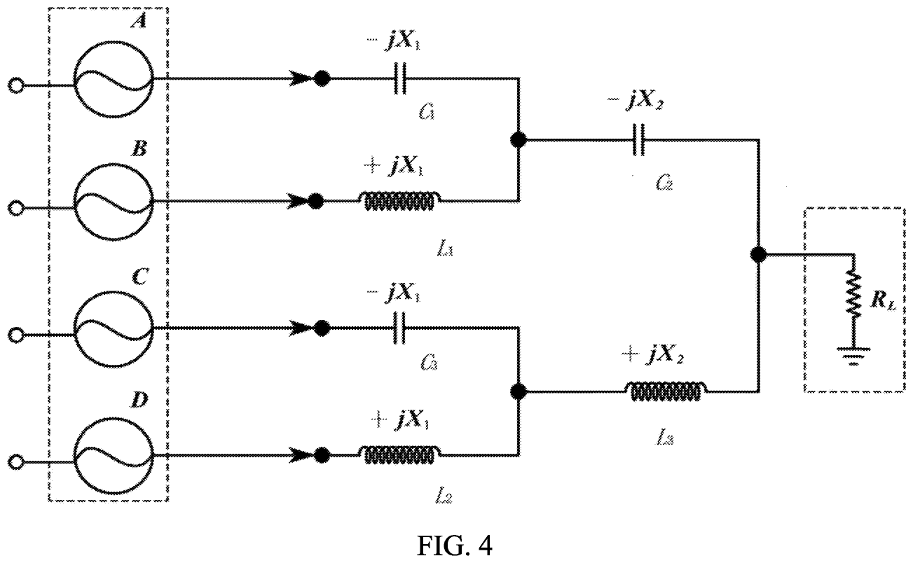

As shown in FIG. 4, the four-way lossless power combiner with wide load impedance variation adaptability includes four bridge arms, namely the first bridge arm, the second bridge arm, the third bridge arm, and the fourth bridge arm. Each bridge arm is connected to an class-E single-transistor power amplifiers with wide load impedance variation adaptability. A, B, C and D are used to represent the four class-E single-transistor power amplifiers with wide load impedance variation adaptability. The first bridge arm includes an equivalent capacitor C₁, the second bridge arm includes an inductor L₁, the parallel combination of the first bridge arm and the second bridge arm is connected to one end of the equivalent capacitor C₂, the third bridge arm includes an equivalent capacitor C₃, the fourth bridge arm includes an equivalent inductor L₂, and the parallel combination of the third bridge arm and the fourth bridge arm is connected to one end of the equivalent inductor L₃, the other end of the equivalent inductance L₃ and the other end of the equivalent capacitor C₂ together serve as the output end of the lossless power combiner with wide load impedance variation adaptability to connect to one end of the load impedance R_{L}, and the other end of the load impedance R_{L} is grounded. It can be understood that the equivalent capacitor in a lossless combiner can be the equivalent capacitor formed by a plurality of different capacitors, and the equivalent inductor can be the equivalent inductor formed by a plurality of different inductors.

The equivalent impedance of each bridge arm satisfies the following:

$${X}_{1} = \frac{{X}_{2}}{{k}_{comb} + \sqrt{{k}_{comb}^{2} - 1}} ; {X}_{2} = \frac{2 {R}_{L}}{{k}_{comb} + 1} ;$$

Wherein, k_{comb} is a maximum degree of non-resistive fluctuation to balance the equivalent load of each bridge arm within a load impedance modulation ratio during an outphasing modulation process. X₁ is the absolute value of the equivalent impedance of the bridge arm, and X₂ is the absolute value of the equivalent impedance of the equivalent capacitor C₂ or the equivalent inductor L₃, as shown in FIG. 4. The equivalent impedance of the equivalent capacitor C₂ is represented as −jX₂, and the equivalent impedance of the equivalent inductor L₃ is represented as +jX₂.

The equivalent impedance of the first bridge arm is equal to the equivalent impedance of the third bridge arm and identical in impedance property, both of which are capacitive. The equivalent impedance of the first bridge arm and the third bridge arm can be represented as −jX₁. The equivalent impedance of the second bridge arm is equal to the equivalent impedance of the fourth bridge arm and identical in impedance property, both of which are inductive. The equivalent impedance of the second bridge arm and the fourth bridge arm can be represented as +jX₁. The equivalent impedance of the first bridge arm is opposite to that of the second bridge arm. The parallel output terminals of the first bridge arm and the second bridge arms have the same equivalent impedance and opposite impedance properties as the parallel output terminals of the third bridge arm and the fourth bridge arm.

By combining the lossless power combiner with wide load impedance variation adaptability with the class E single-transistor power amplifiers and an appropriate outphasing modulation strategy, an overall increase in the output power of the power amplifier can be achieved through power amplifier combining.

In one embodiment, the outphasing modulation strategy is realized by the controller, which generates the gate-control signal according to the out-of-phase angle. The gate-control signals are input to the gates of the four channels of the class-E single-transistor power amplifiers with wide load impedance variation adaptability, that is, the gates of the power amplifier transistors E are controlled, so as to adjust the phase of the output power of the class-E single-transistor power amplifier, and achieve directional modulation of the equivalent load impedance of the power amplifier output end due to this phase adjustment.

The out-of-phase angles are:

$$θ = {cos}^{- 1} ( \sqrt{\frac{4 {V}_{s}^{4} + {P}_{out}^{2} {X}_{1}^{2}}{8 {P}_{out} {R}_{L} {V}_{s}^{2}}} )$$

$$φ = {tan}^{- 1} ( \frac{{P}_{out} {X}_{1}}{2 {V}_{s}^{2}} )$$

Where, θ and φ are both out-of-phase angles, Pₒᵤₜ is the peak power output of the combiner, Vₛ is the peak voltage output of the single channel power amplifier, the peak voltage output of the single channel power amplifier of the four class-E single-transistor power amplifiers is the same and generally does not change with the modulation process, and R_{L} is the load impedance. By utilizing a single-channel class-E single-transistor power amplifier and the load impedance adaptability of the lossless combiner itself, it is possible to design zero voltage switching operating states for different equivalent impedances within the impedance modulation ratio range, that is, to establish corresponding different power amplitudes at each equivalent load within the range. By continuously calculating the modulation angle combination corresponding to the load impedance for control switching, the equivalent impedance value of the load can be equivalently changed to achieve power regulation and switching.

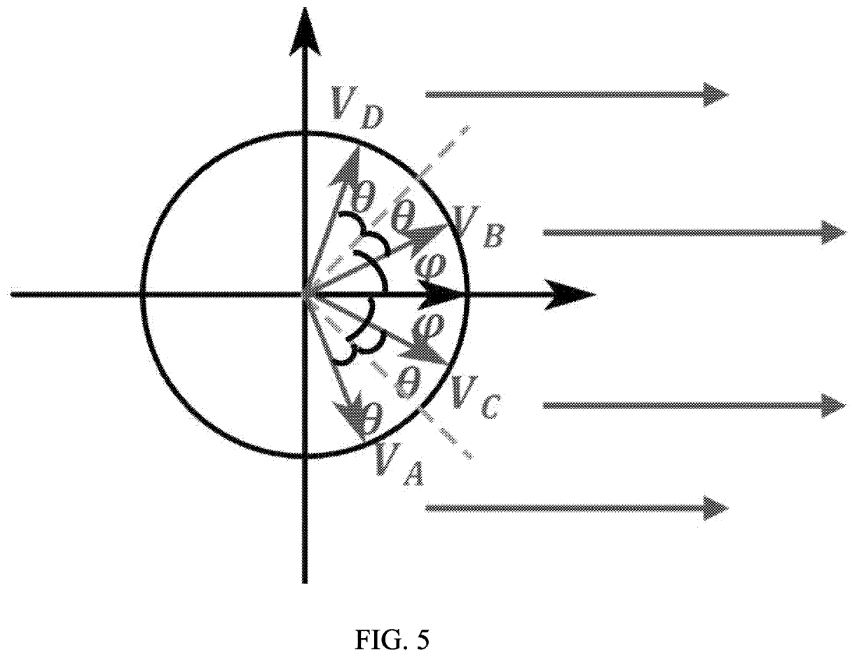

As shown in FIG. 5, the outphasing modulation strategy requires the four channels of the class-E single-transistor power amplifier with wide load impedance variation adaptability to have phase differences in their gate-control signals. To achieve efficient operation, it is necessary to achieve the corresponding outphasing modulation effect according to the phase difference value between each channel indicated in the outphasing modulation strategy. In one example, the load impedance modulation ratio is 10:1, and there are ten sets of the outphasing modulation angles, each set has two angular values, namely θ and φ, and each set of outphasing modulation angles corresponds to an equivalent load impedance. Specifically, based on the outphasing modulation angle combinations and the phase differences between the gate-control signals of the four class-E single-transistor power amplifier with wide load impedance variation adaptability, as shown in FIG. 5, in one example, A, B, C and D respectively represent four sets of class-E single-transistor power amplifiers, and the outputs of the four sets of the class-E single-transistor power amplifiers are respectively represented as V_{A}, V_{B}, V_{C} and V_{D}, with the phase of V_{A} leading. If the phase shift of V_{A} is set to 0, then V_{C} would be 0+2θ, V_{B} would be 0+2φ, and V_{D} would be 0+2θ+2φ. The phase adjustment of the output power of the class-E single-transistor power amplifier is achieved by the phase differences in gate-control signals of the four sets of class-E single-transistor power amplifiers.

That is, the phase shift of the class-E single-transistor power amplifier with wide load impedance variation adaptability connected with the first bridge arm is recorded as zero;

The phase shift of the class-E single-transistor power amplifier with wide load impedance variation adaptability connected with the third bridge arm is adjusted to 2θ;

The phase shift of the class-E single-transistor power amplifier with wide load impedance variation adaptability connected with the second bridge arm is adjusted to 2φ;

The phase shift of the class-E single-transistor power amplifier with wide load impedance variation adaptability connected with the fourth bridge arm is adjusted to 2θ+2φ.

The overall working effects of the class-E single-transistor power amplifiers with wide load impedance variation adaptability and the four-way lossless combiner with wide load impedance variation adaptability are tested. The power supply voltage is set to 15V, and all the above structures are designed with the impedance modulation ratio of 10:1 (equivalent change load impedance range is 12.5Ω-125Ω). For a class-E single-transistor power amplifier, the effective value relationship of its output power is as follows:

$$\frac{{P}_{O} \cdot {R}_{L}}{{V}_{DC}^{2}} = 1.32$$

Where, V_{DC} is the DC (direct current) supply voltage, P_{O} is the effective value of output power, and R_{L} is the load impedance. When the DC supply voltage is 15V and R_{L} is 50Ω, the theoretical output power effective value is 5.94 W, corresponding to a peak power of 11.88 W. A single set of class-E single-transistor power amplifier can achieve a stable peak power of 10 W at the target frequency on a 50Ω load, maintain zero voltage switching operation, with an efficiency of up to 84%, and a −10 dB attenuator was used during testing. The four-way lossless combiner with wide load impedance variation adaptability can achieve the adjustment of the power output range of the four-way lossless combiner with wide load impedance variation adaptability up to 160 W and down to 10 W on 50Ω load under different outphasing modulation combinations, the voltage of the four bridge arms of the four-way lossless combiner wide load impedance variation adaptability remains relatively balanced, and a −30 dB high-power attenuator was used during testing. The test results show that there is a slight phase shift in the output power signal under different outphasing modulation angle combinations. Compared with the heaviest and lightest load cases, this phase shift can reach about 12%. This indicates that in fact, the multi-way lossless combiner is still not ideal within the impedance modulation ratio of 10:1, and some reactive power losses still occur, resulting in a decrease in combining efficiency compared to a single power amplifier. However, this impact is relatively minor, and the success of power combining and outphasing modulation also proves the adaptability of the class-E single-transistor power amplifiers and the four-way lossless combiner with wide load impedance variation adaptability within a impedance modulation ratio of 10:1.

The above description is only the preferred embodiment of this disclosure and is not intended to limit this disclosure. Any modifications, equivalent substitutions, and improvements made within the spirit and principles of this disclosure should be included within the scope of this disclosure.

What is claimed is:

1. An excitation subsystem of an in-situ multi-directional imaging nuclear magnetic resonance logging system, comprising:
four channels of class-E single-transistor power amplifiers with wide load impedance variation adaptability, configured to modulate an output voltage of a power supply to adapt to changes in load impedance;
a four-way lossless power combiner with wide load impedance variation adaptability, comprising four bridge arms, wherein each bridge arm connected to one channel of the class-E single-transistor power amplifiers with wide load impedance variation adaptability, and matched with an impedance modulation ratio of the class-E single-transistor power amplifiers with wide load impedance variation adaptability to integrate an voltage from four output channels for exciting the load;
a controller, configured to generate out-of-phase gate-control signals according to an out-of-phase angle, wherein the out-of-phase gate-control signals are input to gates of the four channels of the class-E single-transistor power amplifiers with wide load impedance variation adaptability, and a phase of output power of the four channels of the class-E single-transistor power amplifiers with wide load impedance variation adaptability is adjusted according to an outphasing modulation strategy.

2. The excitation subsystem of the in-situ multi-directional imaging nuclear magnetic resonance logging system according to claim 1, wherein each channel of the class-E single-transistor power amplifiers with wide load impedance variation adaptability comprises a power amplifier transistor E, a power supply resonant cavity, an output-series resonant cavity, and an output-parallel resonant cavity,
wherein the power supply resonant cavity comprises an inductor L_{f} and a capacitor C_{add}, a first end of the inductor L_{f} is connected to a positive terminal of the power supply, a second end of the inductor L_{f} is connected to a gate of the power amplifier transistor E, a source of the power amplifier transistor E is grounded and connected to a negative terminal of the power supply, the capacitor C_{add} is connected in parallel between a drain and the source of the power amplifier transistor E, and parasitic capacitance of the power amplifier transistor E and the capacitor C_{add} form the capacitance of the power supply resonant cavity;
the output-series resonant cavity comprises an inductor Lₛ and a capacitor Cₛ connected in series, a first end of the inductor Lₛ is connected to the second end of inductor L_{f}, and a second end of inductor Lₛ is connected to a first end of capacitor Cₛ;
the output-parallel resonant cavity comprises an inductor Lₚ and a capacitor Cₚ, one end of the inductor Lₚ is connected to a second end of the capacitor Cₛ and one end of the capacitor Cₚ to serve as an output end of the output-parallel resonant cavity, and the other end of the inductor Lₚ is connected to the other end of the capacitor Cₚ and grounded.

3. The excitation subsystem of the in-situ multi-directional imaging nuclear magnetic resonance logging system according to claim 2, wherein the output-series resonant cavity satisfies:
$${C}_{s} = \frac{1}{2 π {f}_{sw} {R}_{min} {Q}_{s}}$$
Lₛ=Cₛ·(Rₘᵢₙ·Qₛ)
where, f_{sw} is a power amplifier switching frequency, Rₘᵢₙ is a minimum load impedance within a range of load impedance variation adaptability, Qₛ is a design quality factor of the output-series resonant cavity, Cₛ is a capacitance value of the capacitor Cₛ, and Lₛ is an inductance value of the inductor Lₛ.

4. The excitation subsystem of the in-situ multi-directional imaging nuclear magnetic resonance logging system according to claim 2, wherein the output-parallel resonant cavity satisfies:
$$\& {C}_{p} = \frac{{Q}_{p}}{2 π {f}_{sw} {P}_{max}}$$
$${L}_{p} = {( \frac{{R}_{max}}{{Q}_{p}} )}^{2} \cdot {C}_{p}$$
where, Qₚ is a quality factor of the output-parallel resonant cavity, Rₘₐₓ is a maximum load impedance within a range of load impedance variation adaptability, Cₚ represents a capacitance value of capacitor Cₚ, Lₚ represents an inductance value of inductor Lₚ, and f_{sw} is a power amplifier switching frequency.

5. The excitation subsystem of the in-situ multi-directional imaging nuclear magnetic resonance logging system according to claim 2, wherein the power supply resonant cavity satisfies:
\sqrt{L_{f}/C_{f}}=k_{f}Rₘᵢₙ, k_{f}∈[0.2,1.5];
f_{f}=kf_{sw}, k∈[1.3,1.5];
$${L}_{f} = - {k}_{f} {R}_{min} \cdot 2 π {f}_{sw} \cdot ( {L}_{f} {C}_{f} - \frac{1}{{( 2 π {f}_{sw} )}^{2}} ) ;$$
$${L}_{f} {C}_{f} + \frac{1}{{( 2 π {f}_{f} )}^{2}} ;$$
where, k is a resonance factor of the power supply resonant cavity, k_{f} is a impedance design factor, L_{f} is ab inductance value of inductance L_{f}, C_{f} is a capacitance value of the power supply resonant cavity, f_{sw} is a the power amplifier switching frequency, Rₘᵢₙ is a minimum load impedance within a range of load impedance variation adaptability, and f_{f} is a design resonance point frequency of the power supply resonant cavity.

6. The excitation subsystem of the in-situ multi-directional imaging nuclear magnetic resonance logging system according to claim 1, wherein the four-way lossless power combiner with wide load impedance variation adaptability comprises a first bridge arm, a second bridge arm, a third bridge arm, and a fourth bridge arm, an input side of each bridge arm is connected to one channel of the class-E single-transistor power amplifiers with wide load impedance variation adaptability, the first bridge arm comprises an equivalent capacitor C₁, the second bridge arm comprises an equivalent inductor L₁, the first bridge arm is connected in parallel with the second bridge arm and then connected to one end of the equivalent capacitor C₂, the third bridge arm comprises an equivalent capacitor C₃, the fourth bridge arm comprises an equivalent inductor L₂, the third bridge arm is connected in parallel with the fourth bridge arm and then connected to one end of the equivalent inductor L₃, the other end of the equivalent inductance L₃ and the other end of the equivalent capacitance C₂ together serve as output terminals of the four-way lossless power combiner with wide load impedance variation adaptability.

7. The excitation subsystem of the in-situ multi-directional imaging nuclear magnetic resonance logging system according to claim 6, wherein an equivalent impedance of the first bridge arm is equal to an equivalent impedance of the third bridge arm and identical in impedance property, an equivalent impedance of the second bridge arm is equal to an equivalent impedance of the fourth bridge arm and identical in impedance property, the equivalent impedance of the first bridge arm is opposite to the equivalent impedance of the second bridge arm, and an equivalent impedance of parallel output terminals of the first bridge arm and the second bridge arm are equal to an equivalent impedance of parallel output terminals of the third bridge arm and the fourth bridge arm but with opposite impedance properties.

8. The excitation subsystem of the in-situ multi-directional imaging nuclear magnetic resonance logging system according to claim 6, wherein the equivalent impedance of each bridge arm satisfies:
$${X}_{1} = \frac{{X}_{2}}{{k}_{comb} + \sqrt{{k}_{comb}^{2} - 1}} ; {X}_{2} = \frac{2 {R}_{L}}{{k}_{comb} + 1} ;$$
where, k_{comb} is a maximum degree of non-resistive fluctuation to balance the equivalent load of each bridge arm within a load impedance modulation ratio during an outphasing modulation process, R_{L} is the load impedance, X₁ is an absolute value of the equivalent impedance of the bridge arm, and X₂ is an absolute value of the equivalent impedance of the equivalent inductance L₃ or the equivalent capacitance C₂.

9. The excitation subsystem of the in-situ multi-directional imaging nuclear magnetic resonance logging system according to claim 8, wherein outphasing modulation angles are:
$$θ = {cos}^{- 1} ( \sqrt{\frac{4 {V}_{s}^{4} + {P}_{out}^{2} {X}_{1}^{2}}{8 {P}_{out} {R}_{L} {V}_{s}^{2}}} ) ;$$
$$φ = {tan}^{- 1} ( \frac{{P}_{out} {X}_{1}}{2 {V}_{s}^{2}} ) ;$$
where, θ and φ are both the outphasing modulation angles, Pₒᵤₜ is a peak power output of a combined channel, and Vₛ is a peak voltage output of a single-channel power amplifier.

10. The excitation subsystem of the in-situ multi-directional imaging nuclear magnetic resonance logging system according to claim 6, wherein phases of output power of the four channels of the class-E single-transistor power amplifiers with wide load impedance variation adaptability is adjusted according to the outphasing modulation process strategy, comprising:
a phase shift of the class-E single-transistor power amplifiers with wide load impedance variation adaptability connected to the first bridge arm is recorded as zero;
a phase shift of the class-E single-transistor power amplifiers with wide load impedance variation adaptability connected to the third bridge arm is adjusted as 2θ;
a phase shift of the class-E single-transistor power amplifiers with wide load impedance variation adaptability connected to the second bridge arm is adjusted as 2φ;
a phase shift of the class-E single-transistor power amplifiers with wide load impedance variation adaptability connected to the fourth bridge arm is adjusted as 2θ+2φ.

11. The excitation subsystem of the in-situ multi-directional imaging nuclear magnetic resonance logging system according to claim 7, wherein the equivalent impedance of each bridge arm satisfies:
$${X}_{1} = \frac{{X}_{2}}{{k}_{comb} + \sqrt{{k}_{comb}^{2} - 1}} ; {X}_{2} = \frac{2 {R}_{L}}{{k}_{comb} + 1} ;$$
where, k_{comb} is a maximum degree of non-resistive fluctuation to balance the equivalent load of each bridge arm within a load impedance modulation ratio during an outphasing modulation process, R_{L} is the load impedance, X₁ is an absolute value of the equivalent impedance of the bridge arm, and X₂ is an absolute value of the equivalent impedance of the equivalent inductance L₃ or the equivalent capacitance C₂.

12. The excitation subsystem of the in-situ multi-directional imaging nuclear magnetic resonance logging system according to claim 11, wherein outphasing modulation angles are:
$$θ = {cos}^{- 1} ( \sqrt{\frac{4 {V}_{s}^{4} + {P}_{out}^{2} {X}_{1}^{2}}{8 {P}_{out} {R}_{L} {V}_{s}^{2}}} ) ;$$
$$φ = {tan}^{- 1} ( \frac{{P}_{out} {X}_{1}}{2 {V}_{s}^{2}} ) ;$$
where, θ and φ are both the outphasing modulation angles, Pₒᵤₜ is a peak power output of a combined channel, and Vₛ is a peak voltage output of a single-channel power amplifier.
